(19) United States
(12) Patent Application Publication
(10) Pub. No.: US 2012/0231218 A1
(43) Pub. Date: Sep. 13, 2012

(54) SUBSTRATE, MANUFACTURING METHOD OF SUBSTRATE, SAW DEVICE AND DEVICE

(75) Inventors: Shigeru Nakayama, Osaka-shi (JP); Yutaka Tsuji, Osaka-shi (JP)

(73) Assignee: Sumitomo Electric Industries, Ltd., Osaka-shi (JP)

(21) Appl. No.: 13/496,968

(22) PCT Filed: Sep. 16, 2010
(86) PCT No.: PCT/JP10/66054

§ 371 Date: Jun. 4, 2012

(30) Foreign Application Priority Data
Sep. 18, 2009 (JP) 2009-217514
Sep. 7, 2010 (JP) 2010-199908

(51) Int. Cl. C04B 35/10; H03H 9/25; H05K 13/00; B32B 33/00

(52) U.S. Cl. 428/141; 216/38; 501/153

(57) ABSTRACT

Provided is a substrate that can be made to have a suitable strength with low-cost and that can be bonded firmly to a piezoelectric substrate. The substrate, which is for SAW devices, consists of spinel, and the PV value of the difference in level of one of the main faces of the substrate is 2 nm to 8 nm inclusive. The average roughness (Ra) value of the one of the main faces of the substrate is preferably 0.01 nm to 3.0 nm inclusive, more preferably 0.01 nm to 0.5 nm inclusive. Also the Young's modulus of the spinel substrate, which is for the SAW device or other devices, is preferably 150 GPa to 350 GPa inclusive.

### CROSS-REFERENCE TO RELATED APPLICATIONS

The present application is a national stage application of PCT Application No. PCT/JP2010/066054, filed Sep. 16, 2010, and claims priority to Japanese Application No. 2009-217514, filed on Sep. 18, 2009 and Japanese Application No. 2010-199908, filed on Sep. 7, 2010, then entire contents of which are herein incorporated by reference.

### TECHNICAL FIELD

The present invention relates to a substrate for an SAW device, a method of manufacturing the substrate for an SAW device, an SAW device using the substrate, a substrate for a different device and the device using the substrate.

### BACKGROUND ART

In a mobile telephone, an electronic component referred to as an SAW filter for cutting noises in electric signals and for transmitting/receiving electric signals of only the desired frequencies is incorporated. The SAW (Surface Acoustic Wave) filter means a surface wave filter. In an SAW filter, a piezoelectric substrate formed of a material having piezoelectric effect is used. Generally, an SAW filter is used bonded on a substrate having superior radiation performance (holding substrate), to radiate heat generated by the piezoelectric substrate at the time of use.

By way of example, Japanese Patent Laying-Open No. 2008-301066 (Patent Literature 1) discloses a composite substrate including a holding substrate having low coefficient of thermal expansion and a piezoelectric substrate of an SAW filter bonded to each other.

A method of bonding the piezoelectric substrate and the holding substrate is disclosed, for example, in Japanese Patent Laying-Open No. 2004-343359 (Patent Literature 2). Specifically, a piezoelectric substrate and a holding substrate are washed to remove impurities on bonding surfaces of the two substrates and, thereafter, the bonding surface or surfaces are irradiated with plasma, neutralized beam or ion beam of oxygen or inert gas, whereby remaining impurities are removed and the surface layer of the bonding surface or surfaces is activated. With the activated bonding surface or surfaces, the piezoelectric substrate and the holding substrate are bonded.

A piezoelectric substrate deforms as it receives stress from input electric signals. Therefore, the holding substrate mounting the piezoelectric substrate must have high strength. For this reason, some of conventionally used holding substrates for mounting piezoelectric substrate for the SAW filter are formed of sapphire, as described, for example, in FUJITSU SAW filter (Non-Patent Literature 1).

### CITATION LIST

### Patent Literature

PTL 1: Japanese Patent Laying-Open No. 2008-301066

PTL 2: Japanese Patent Laying-Open No. 2004-343359

### NON PATENT LITERATURE

NPL 1: “SAW Filter”, [Online], June 2008 [Searched on Sep. 9, 2009] on the Internet, <URL:http://jp.fujitsu.com/group/labs/downloads/business/activities/activities-2/fujitsu-labs-netdev-001.pdf>

### SUMMARY OF INVENTION

### Technical Problem

As the holding substrates disclosed in each of the documents cited above, mainly, sapphire single crystal substrates are used. Single crystal of sapphire, however, is typically very expensive. This leads to high-cost of production of substrates for mounting the SAW filter formed of sapphire.

Though sapphire has sufficient strength as a substrate for mounting the SAW filter, it has very high hardness and, therefore, formed substrate is sometimes prone to damage such as chipping. Further, due to the high hardness, cutting work of sapphire to a substrate of a desired shape is difficult. Consequently, speed of cutting cannot be increased, further leading to higher cost of sapphire substrates. Further, since sapphire has cleavage characteristic particular to single crystal, it is highly possible that the sapphire holding substrate split due to stress applied by the deformation of piezoelectric substrate.

In Patent Literature 1, for example, the holding substrate and the piezoelectric substrate are bonded by an adhesive. For highly accurate bonding of piezoelectric substrate to the holding substrate, however, bonding utilizing van der Waals interaction between the two substrates is preferred.

When substrates are bonded using van der Waals interaction, it is preferred that bonding surfaces have superior flatness. Therefore, it is preferred that the bonding surface of holding substrate to the piezoelectric substrate is subjected to three types of polishing including rough polishing, normal polishing and polishing with diamond abrasive grains. However, even after the bonding surface of holding substrate is polished with diamond abrasive grains, when it is to be joined to the bonding surface of piezoelectric substrate, many voids tend to generate between the two bonding surfaces, resulting in failure of bonding.

According to Patent Literature 2, the bonding surface is irradiated with ion beams or plasma, so that the bonding surface is activated and an amorphous layer is formed, and then, the bonding surfaces are joined. Patent Literature 2, however, is silent about the polishing process of bonding surface. Therefore, even if the bonding method disclosed in this document is used, there is still a possibility of bonding failure, resulting from roughness or difference in level of the bonding surface.

The present invention was made in view of the above-described problems. Its object is to provide a substrate having appropriate strength and allowing firm bonding to a piezoelectric substrate by van der Waals interaction at a lower cost, a method of manufacturing the substrate, an SAW device and devices using the substrate.

### Solution to Problem

According to an aspect, the present invention provides a substrate formed of spinel for an SAW device.

The substrate in accordance with the present invention is a substrate formed of spinel for an SAW device, wherein one main surface of the substrate has a value PV representing difference in level of at least 2 nm and at most 8 nm. Here, the main surface refers to a major surface of largest area among the surfaces.

As a result of intensive study, the inventors have found that spinel, which is mainly used in the field of optical devices, may possibly be used in place of sapphire, as the holding substrate for mounting an SAW device such as the SAW filter described above. Physical properties such as strength of spinel are close to those of sapphire, including the strength. It has been found that a holding substrate for SAW devices formed of spinel can practically be used, similar to the holding substrate for SAW devices formed of sapphire. By way of example, an SAW device holding substrate formed of spinel exhibits practically well acceptable strength (Young's modulus), though not as high as that of an SAW device holding substrate formed of sapphire. Further, spinel has coefficient of thermal conductivity practically sufficient to radiate heat generated by the piezoelectric substrate forming the SAW device.

Conventionally, however, it has been technical common sense to use a single crystal body such as sapphire for the substrate for holding SAW devices. Among those skilled in the art, spinel, which is a polycrystalline body, has been inconceivable as a candidate for substrate material. Going against the common sense, the inventors continued study and came to found that spinel could be used for the SAW device holding substrate. If an SAW device holding substrate is formed using spinel (spinel holding substrate) in place of sapphire, production cost of the substrate can be reduced.

Further, as a result of intensive study, the inventors have found that a PV (peak-to-valley) value representing difference in level of the bonding surface of spinel holding substrate to be bonded to the piezoelectric substrate forming an SAW filter or the like has an influence on the state of bonding at the bonding surface. Here, the value PV represents difference in level (unevenness) between the highest peak and the lowest valley of a cross-sectional curve of the surface.

When bonding to a piezoelectric substrate is to be attained utilizing van der Waals interaction, satisfactory bonding can be attained between the bonding surface and the piezoelectric substrate, if the bonding surface of spinel holding substrate is flat. As a result of intensive study, the inventors have found that satisfactory bonding to the piezoelectric substrate can be attained if the PV value of the bonding surface of the substrate formed of spinel is at least 2 nm and at most 8 nm. Thus, the main surface of the substrate to be bonded to the piezoelectric substrate can be bonded in a satisfactory manner utilizing van der Waals interaction, to the piezoelectric material forming the piezoelectric substrate.

In the substrate mentioned above, preferably, one main surface of the substrate has a value Ra of average roughness of at least 0.01 nm and at most 3.0 nm. Here, the main surface refers to a major surface of largest area among the surfaces.

In the substrate mentioned above, more preferably, one main surface of the substrate has a value Ra of average roughness of at least 0.01 nm and at most 0.5 nm.

Since sapphire crystal is single crystal, a substrate formed of sapphire can easily be processed to realize a good value Ra of average roughness of the main surface. On the other hand, spinel has polycrystalline structure and, hence, it generally has high surface roughness at the boundary of adjacent crystal grains. The inventors have found, however, that even the substrate using polycrystalline spinel can attain superior flatness with the value Ra of average roughness of the main surface being at least 0.01 nm and at most 3.0 nm (more preferably, 0.01 nm to 0.5 nm), by controlling processing method. Therefore, the main surface of the substrate to be bonded to the piezoelectric substrate can satisfactorily be bonded to the piezoelectric material forming the piezoelectric substrate, utilizing van der Waals interaction.

From the foregoing, the SAW device using the substrate formed of spinel is inexpensive as compared with the conventional SAW device using sapphire, while the substrate is comparable to the substrate formed of sapphire and has sufficient strength to be practically usable and, therefore, stable electric signal transmission characteristic can be realized.

The present invention provides a method of manufacturing a substrate formed of spinel for an SAW device, including the steps of: preparing the substrate; and conducting chemical mechanical polishing on one main surface of the substrate.

The PV value of 2 nm to 8 nm and Ra value of at least 0.01 nm and at most 3.0 nm (0.01 nm to 0.5 nm) of the main surface of the substrate in accordance with the present invention can be realized by performing CMP (Chemical Mechanical Polishing) on one of the main surfaces of the substrate. Therefore, if chemical mechanical polishing is conducted on the holding substrate formed of spinel, the substrate attains satisfactory bonding to the piezoelectric substrate utilizing van der Waals interaction. Specifically, the device using the substrate formed of spinel is inexpensive as compared with the conventional device using sapphire, while the substrate is comparable to the substrate formed of sapphire and has sufficient strength and heat radiation characteristic to be practically usable and, therefore, stable electric signal transmission characteristic can be realized.

The SAW device using the substrate formed of spinel as described above is inexpensive as compared with the conventional SAW device using sapphire, while the substrate is comparable to the substrate formed of sapphire and has sufficient strength to be practically usable and, therefore, stable electric signal transmission characteristic can be realized.

According to another aspect, the present invention provides a substrate formed of spinel for a device. Here, for example, the device refers to a filter for a high-frequency transmitter other than the SAW filter for a portable telephone. The substrate formed of spinel can also be used in place of the substrate formed of sapphire, as the substrate for mounting such a device. Specifically, the device using the substrate formed of spinel as described above is inexpensive as compared with the conventional device using sapphire substrate, while the substrate is comparable to the substrate formed of sapphire and has sufficient strength to be practically usable and, therefore, stable electric signal transmission characteristic can be realized.

Preferably, the substrate formed of spinel for the SAW device or other device should preferably have Young's modulus of at least 150 GPa and at most 350 GPa. Using the spinel having the Young's modulus in the range above, processing for forming the substrate can be facilitated. Thus, cost of processing can further be reduced. Further, spinel having the Young's modulus in the range above has practically acceptable strength.

### Advantageous Effects of Invention

By the present invention, a spinel holding substrate having practically acceptable strength and attaining satisfactory bonding to a piezoelectric substrate such as an SAW filter using van der Waals interaction can be provided at a low cost. By the present invention, a substrate formed of spinel for an SAW device or other devices having practically acceptable strength can be provided at a low cost.

### BRIEF DESCRIPTION OF DRAWINGS

FIG. 1 is a perspective view showing an appearance of the substrate in accordance with an embodiment of the invention.

FIG. 2 is a perspective view showing an appearance of an SAW filter using the substrate of FIG. 1.

FIG. 3 is a perspective view showing an appearance of a BAW filter using the substrate of FIG. 1.

FIG. 4 is a schematic cross-sectional view showing an exemplary cross-section of a portion along the line IV, V-IV, V of FIG. 3.

FIG. 5 is a schematic cross-sectional view showing another exemplary cross-section, different from FIG. 4, of a portion along the line IV, V-IV, V of FIG. 3.

FIG. 6 is a flowchart representing the method of manufacturing the substrate in accordance with the present embodiment.

FIG. 7 is a flowchart representing the method of polishing the substrate in accordance with the present embodiment.

### DESCRIPTION OF EMBODIMENTS

In the following, embodiments of the present invention will be described with reference to the figures.

As shown in FIG. 1, a substrate 1 in accordance with the present embodiment is a wafer formed of spinel, of which main surface 1a has a diameter of 4 inches. By way of example, MgO.nAl₂O₃ (1≦n≦3) is used as the spinel for forming substrate 1.

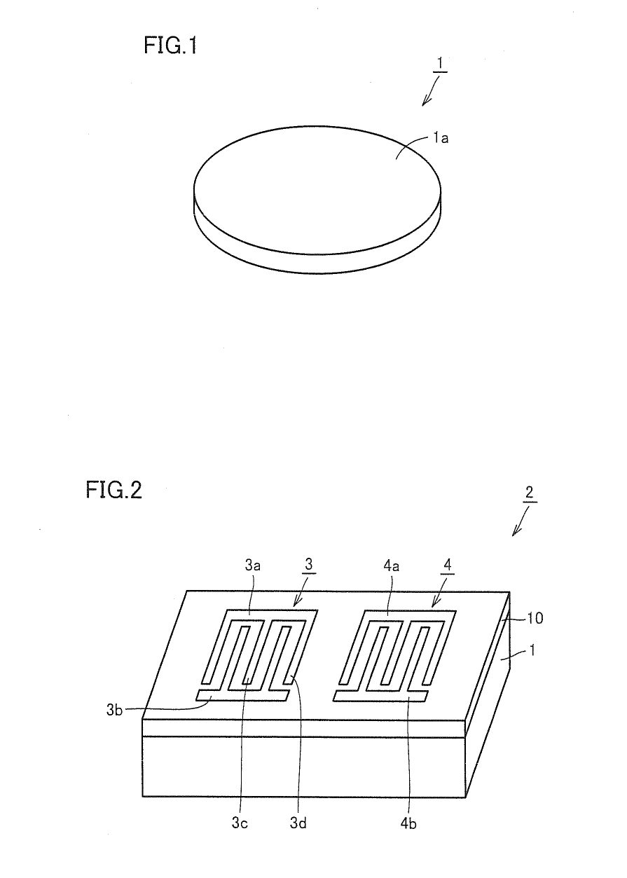

Substrate 1 may be used as a component for heat radiation in an electronic device, or it may be used as a filter for a high-frequency transmitter. Alternatively, it may be used as a substrate for electronic device used as an auto component. Besides, substrate 1 may be used as a holding substrate for mounting (bonding) a piezoelectric substrate 10 forming an SAW filter 2 as an SAW device, as shown in FIG. 2.

Substrate 1 shown in FIG. 2 is a part of substrate 1 shown in FIG. 1. On a main surface 1a of substrate 1, a piezoelectric substrate 10 is bonded. On a main surface of piezoelectric substrate 10 opposite to the main surface facing substrate 1 (on the upper main surface in FIG. 2), comb-shaped electrodes 3 and 4 of metal thin film are formed.

Assume, for example, that electrode 3 of FIG. 2 is an electrode for inputting an acoustic wave signal, and electrode 4 is an electrode for outputting the acoustic wave signal. Electrode 3 consists of a set of first electrode 3a and second electrode 3b, and electrode 4 consists of a set of first electrode 4a and second electrode 4b. Between the first and second electrodes 3a and 3b, an AC voltage, for example, is applied, and between the first and second electrodes 4a and 4b, an AC voltage, for example, is applied. To a current caused by the AC voltage applied between the first and second electrodes 3a and 3b, an acoustic wave signal is input. Then, crystal grains (atoms) forming piezoelectric substrate 10 having electrodes 3 and 4 formed thereon receive stress and, because of piezoelectric effect, the grains move closer to or away from each other. As a result, the main surface of piezoelectric substrate 10 vibrates like ripples.

As shown in FIG. 2, however, the first electrodes 3a and 4a and second electrodes 3b and 4b each have comb-shape. Therefore, of acoustic wave signals input to electrode 3, for example, only the acoustic wave signals having a wavelength corresponding to the distance between comb components 3c and 3d resonate and propagate to the outside from the output side electrode 4. Specifically, acoustic signals having wavelength different from the wavelength mentioned above are not propagated to the outside from the output side electrode 4, and cut off in SAW filter 2. Because of such a principle, SAW filter 2 functions to output only the acoustic wave signals having a desired wavelength to the outside and hence, functions to cut off acoustic wave signals having wavelength other than the desired wavelength (that is, noise) and thereby to remove noise from the output signals.

Particularly, when substrate 1 is used as a base substrate for the SAW filter shown in FIG. 2, one of the main surfaces of substrate 1, specifically, main surface 1a to be bonded to piezoelectric substrate 10, should preferably be joined to crystal grains (molecules) forming piezoelectric body 10 by van der Waals interaction. More specifically, molecules of the material forming piezoelectric substrate 10 should preferably be joined to molecules of spinel forming substrate 10 by van der Waals interaction. It is difficult to bond piezoelectric substrate 10 to main surface 1a of the substrate formed of spinel by using, for example, an adhesive. Therefore, in order to have piezoelectric substrate 10 mounted stably on main surface 1a of substrate 1 formed of spinel, it is preferred that piezoelectric substrate 10 be firmly bonded on main surface 1a using van der Waals interaction.

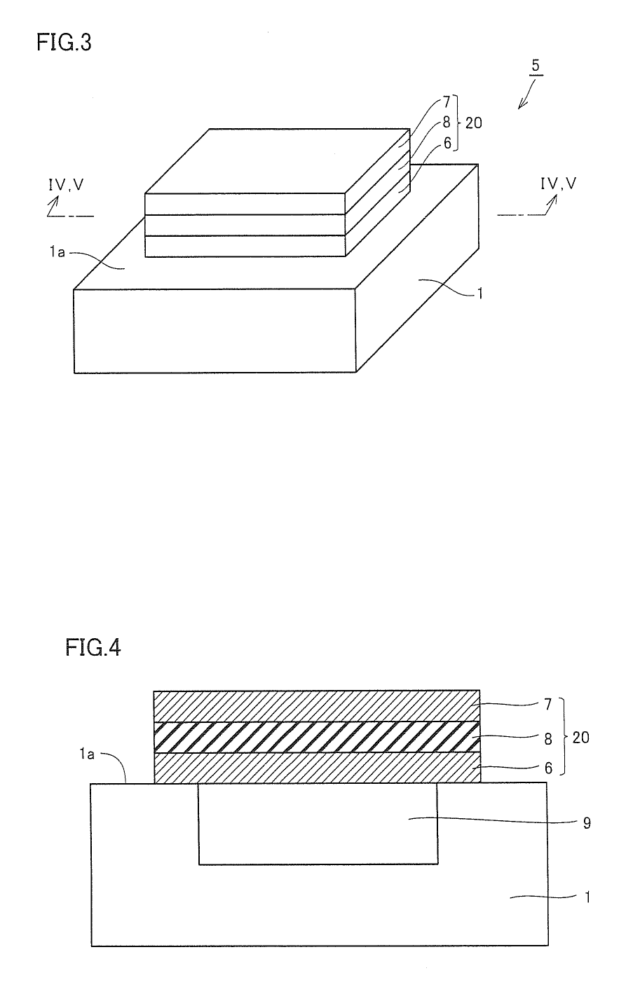

Further, substrate 1 formed of spinel in accordance with the present embodiment may be used as a holding substrate for mounting (bonding) a BAW (Bulk Acoustic Wave) filter 5 having a resonator 20 (consisting of lower and upper electrodes 6 and 7 and a piezoelectric film 8 positioned therebetween) mounted (bonded) on main surface 1a of substrate 1 as shown, for example, in FIG. 3.

Lower and upper electrodes 6 and 7 may preferably be formed of generally known metal material used for forming electrodes, such as molybdenum. Further, piezoelectric film 8 may preferably be formed of ceramic material such as MN (aluminum nitride) or ZnO (zinc oxide).

In BAW filter 5, lower electrode 6 of resonator 20 and main surface 1a of substrate 1 are bonded by van der Waals interaction, as in the case of piezoelectric substrate 10 of SAW filter 2 and main surface 1a of substrate 1.

By way of example, BAW filter 5 may be an FBAR (Film Bulk Acoustic Resonator) type device having such a structure as shown in FIG. 4, or it may be an SMR (Solid Mounted Resonator) type device having such a structure as shown in FIG. 5. For instance, a BAW filter 5 of FBAR type shown in FIG. 4 is a BAW filter having a hollow cavity 9 formed to a prescribed depth from main surface 1a, with part of resonator 20 facing hollow cavity 9. BAW filter 5 of SMR type shown in FIG. 5 is a BAW filter having a plurality of low impedance layers 11 and high impedance layers 12 stacked alternately on substrate 1.

SAW filter 2 utilizes surface wave (surface acoustic wave), whereas BAW filter 5 utilizes bulk elastic wave, and it operates using resonant vibration of piezoelectric film 8 itself For example, in FBAR type BAW filter 5 shown in FIG. 4, piezoelectric film 8 vibrates freely utilizing hollow cavity 9 below resonator 20. In SMR type BAW filter 5 shown in FIG. 5, elastic wave proceeding from the upper to lower portion of FIG. 5, for example, is reflected by low impedance film 11 and high impedance film 12 as an acoustic multilayer provided below resonator 20, and the wave reaches and vibrates piezoelectric film 8.

When piezoelectric film 8 vibrates, only the acoustic wave signals having a specific wavelength resonate and are propagated to the outside from an output side electrode (for example, upper electrode 7), as in the case where piezoelectric substrate 10 vibrates in SAW filter 2. Thus, noise in the output signals can be removed.

In order to have piezoelectric substrate 10 mounted stably on main surface 1a of substrate 1 formed of spinel using van der Waals interaction, main surface 1a should preferably have superior flatness. Specifically, it is preferred that the PV value representing difference in level of main surface 1a is at least 2 nm and at most 8 nm. Here, PV means PV particularly at a portion of main surface 1a which is directly bonded to the bonding surface of piezoelectric substrate 10.

With the value PV of 2 nm to 8 nm, main surface 1a comes to have superior flatness. Therefore, substrate 1 as the holding substrate and piezoelectric substrate 10 can be firmly and stably bonded utilizing van der Waals interaction, with main surface 1a serving as a bonding surface. In order to have the value PV smaller than 2 nm, processing of main surface 1a to have extremely high flatness becomes necessary, which involves much increased cost. Therefore, at least 2 nm represents the PV value that can be attained at a reasonable cost and reasonable time of processing. From the viewpoint of reasonable processing cost and securing bonding strength of piezoelectric substrate 10, more preferable PV value is at least 4 nm and at most 6 nm. Here, PV means PV particularly at a portion of main surface 1a which is directly bonded to the bonding surface of piezoelectric substrate 10.

Further, preferably, main surface 1a of substrate 1 has arithmetic average roughness Ra of at least 0.01 nm and at most 3.0 nm, and more preferably, at least 0.01 nm and at most 0.5 nm. With the value Ra of 3.0 nm or smaller, main surface 1a comes to have superior flatness. Further, with the value Ra of 0.5 nm or smaller, main surface 1a comes to have still higher flatness. Therefore, holding substrate 1 and piezoelectric substrate 10 can be firmly and stably bonded utilizing van der Waals interaction, with main surface 1a serving as a bonding surface.

In order to have the value Ra smaller than 0.01 nm, processing of main surface 1a to have extremely high flatness becomes necessary, which involves much increased cost. Therefore, at least 0.01 nm represents the Ra value that can be attained at a reasonable cost and reasonable time of processing. From the viewpoint of reasonable processing cost and securing bonding strength of piezoelectric substrate 10, preferable Ra value mentioned above is at least 0.01 nm and at most 3.0 nm, and more preferably, at least 0.01 nm and at most 0.5 nm.

It is noted, however, that the above-described flatness of main surface 1a is not always required, depending on the intended use of the substrate. For example, it is not required when substrate is used as a substrate for a device other than SAW filter 2 or BAW filter 5, such as a filter for high-frequency transmitter as described above.

Substrate 1 supports piezoelectric substrate 10 and resonator 20 that vibrate. Therefore, considerable stress is applied to substrate 1. Further, when piezoelectric substrate 10 operates, piezoelectric substrate 10 generates heat, and the heat propagates to substrate 1. Specifically, at this time, thermal stress generates in substrate 1. Therefore, substrate 1 should preferably have considerably high strength. Even when substrate 1 is used as a substrate for devices other than SAW filter 2 described above, substrate 1 may possibly be placed under severe conditions and, therefore, substrate 1 should preferably have considerably high strength as when substrate 1 is used for SAW filter 2.

Generally, a structure having higher Young's modulus has higher strength, and a structure having lower Young's modulus has lower strength. Therefore, to ensure strength high enough to withstand use under the conditions described above, substrate 1 should preferably have Young's modulus of at least 150 GPa and at most 350 GPa. With Young's modulus of 150 GPa or higher, substrate 1 has sufficient strength to withstand use under the above-described conditions. Further, generally, a structure having higher Young's modulus has higher hardness, and a structure having lower Young's modulus has lower hardness. Therefore, if Young's modulus of substrate 1 exceeds 350 GPa, hardness of substrate 1 comes to be excessively high, resulting in high possibility of chipping. Further, if Young's modulus of substrate 1 exceeds 350 GPa, hardness of substrate 1 comes to be excessively high, and processing becomes difficult. Therefore, from the viewpoint of ensuring appropriate strength and preventing defects such as chipping, it is preferred that substrate 1 have Young's modulus in the range described above and, particularly, at least 180 GPa and at most 300 GPa is the most preferable range.

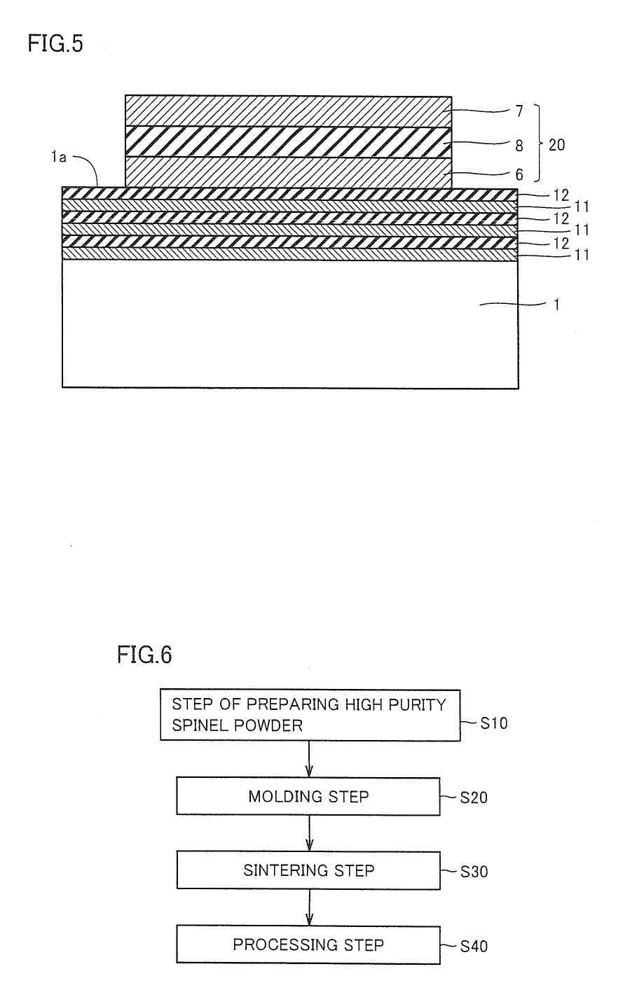

Next, a method of manufacturing substrate 1 will be described. As shown in the flowchart of FIG. 6, first, the step of preparing high purity spinel powder (S10) is executed. Specifically, this is the step of preparing spinel powder as the material for forming substrate 1 of spinel. More specifically, spinel powder represented by the composition formula of MgO.nAl₂O₃ (1≦n≦3), having average grain diameter of at least 0.1 μm and at most 0.3 μm and purity of 99.5% or higher is preferably prepared.

In order to prepare the spinel powder having the composition described above, it is preferred to mix MgO (magnesium oxide) powder and Al₂O₃ (alumina) powder to a mixture ratio (molar ratio) of 1≦Al₂O₃/MgO≦3.

Here, the grain diameter of powder grains means the value of diameter of powder cross-section at a portion where accumulated volume as the sum of powder volumes added from the side of smaller grain size to the side of larger grain size reaches 50%, when the grain size is measured using particle size distribution measurement by laser diffraction/scattering method. The particle size distribution measurement specifically refers to a method of measuring diameter of powder particles or grains, by analyzing scattering intensity distribution of scattered light of laser beam directed to powder particles. The average value of grain diameter of a plurality of powder grains included in the prepared spinel powder is the above-mentioned average grain diameter.

Thereafter, the molding step (S20) shown in FIG. 6 is executed. Specifically, molding by press molding or CIP (Cold Isostatic Pressing) is executed. More specifically, the MgAl₂O₄ (MgO.nAl₂O₃) powder prepared at step (S10) is first subjected to preforming by press molding, followed by CIP, to obtain a molded body. Here, only one of press molding and CIP may be executed, or both may be executed. For example, press molding may be executed and thereafter CIP may be executed.

For press molding, use of pressure of at least 10 MPa and at most 300 MPa, and particularly, pressure of 20 MPa is preferred. In CIP, use of pressure, for example, of at least 160 MPa and at most 250 MPa, and particularly, at least 180 MPa and at most 230 MPa is preferred.

Next, the sintering step (S30) shown in FIG. 6 is executed. As the sintering step, preferably, vacuum sintering method in which a molded body is sintered placed in vacuum atmosphere, or HIP (Hot Isostatic Pressing) in which a molded body is pressurized and sintered in an argon gas atmosphere is used. In place of the above method, hot pressing may be used. Here, only one of vacuum sintering and HIP may be executed, or a plurality of methods may be executed, for example, HIP may be executed following vacuum sintering. Further, after HIP is performed, thermal processing may be executed again.

In vacuum sintering, specifically, the molded body is placed in a vacuum atmosphere, heated to at least 1600° C. and at most 1800° C., while applying pressure of at least 1600 MPa and at most 1850 MPa, and kept for at least one hour and at most three hours. In this manner, a sintered body having density of 95% or higher can be formed. In HIP, the sintered body (or the molded body not subjected to sintering by hot press) is placed in an argon atmosphere, heated to at least 1600° C. and at most 1900° C. while applying pressure of at least 150 MPa and at most 250 MPa, and kept for at least one hour and at most three hours, whereby sintering is done. By the sintering at the pressure and temperature as mentioned above, the density of formed sintered body comes to satisfy the conditions of strength (Young's modulus) required of the eventually formed substrate. The reason for this is that composition change to the spinel sintered body is caused by the pressure, and voids in the sintered body are removed by diffusion mechanism.

The sintered body sintered in the above-described manner is subjected to processing step (S40) as shown in FIG. 6. Specifically, the sintered body is first cut (cutting process) by dicing, to a desired thickness (of substrate 1). Thus, a base of substrate 1 having a desired thickness is completed. Here, the desired thickness should preferably be determined in consideration of the thickness of finally formed substrate 1 and the margin for polishing of main surface 1a of substrate 1 in the subsequent steps.

Next, the main surface of the base of substrate 1 is polished. Specifically, this is the step of polishing main surface 1a of substrate 1 to be finally formed to have the desired value Ra of average roughness. Particularly, if substrate 1 is used as the substrate for SAW filter, it is preferred to have main surface 1a polished to attain the desired values of PV and Ra, as described above.

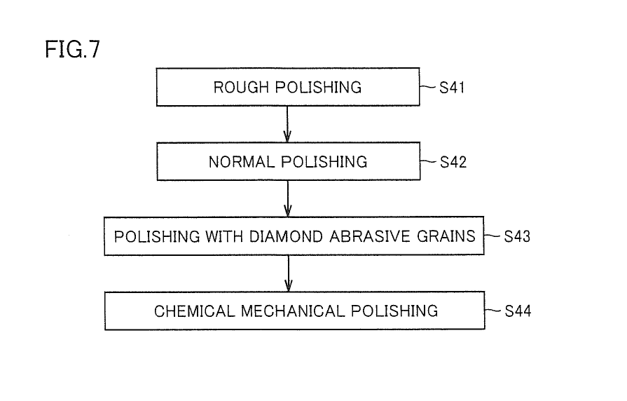

Polishing of main surface 1a of substrate 1 to attain superior flatness preferably includes four stages of polishing, that is, rough polishing, normal polishing, polishing with diamond abrasive grains and CMP, executed successively, as shown in FIG. 7. Specifically, in the rough polishing as the first stage (S41) and in the normal polishing as the second stage (S42), main surface 1a is mirror-polished using a polisher. Here, in rough polishing and normal polishing, the count of abrasive grains used for polishing differs. Specifically, in rough polishing, GC grinder of which abrasive grains have counts #800 to #2000 is preferably used, and in normal polishing, diamond grinder of which abrasive grains have grain diameter of 3 to 5 μm is preferably used.

Next, polishing as a finishing process of the third stage (S43) is preferably executed using diamond abrasive grains. Diamond abrasive grains have very high hardness and very small average grain diameter of about 0.5 μm to 1.0 μm. Therefore, diamond abrasive grains are suitably used as abrasive grains for highly precise mirror finish. Polishing process is done for 10 minutes, for example, using the abrasive grains. In the chemical mechanical polishing as the fourth stage (S44), chemical polisher and polishing pad are used, and ups and downs on the wafer surface is ground down and made flat by combined action of chemical function and mechanical polishing. In this manner, the difference in level at the crystal grain boundary of spinel as the polycrystalline body can be made flat, and the value PV of main surface 1a after CMP can be made smaller. Further, as the main surface 1a is made flat by chemical mechanical polishing (S44), the value Ra in addition to PV can also be made smaller.

In this manner, highly flat main surface 1a having difference in level PV of 2 nm to 8 nm and average roughness Ra of at least 0.01 nm and at most 3.0 nm (at most 0.5 nm) described above can be realized. Therefore, substrate 1 particularly for SAW filter can satisfactorily be bonded to the main surface of piezoelectric substrate 10 by van der Waals interaction.

When the substrate formed of spinel is used, for example, for a filter of a high-frequency transmitter, such a high flatness as required for the spinel substrate for a SAW filter as described above is unnecessary. In this case, for the three stages of polishing described above, it is preferable to use abrasive grains used for forming substrate 1 for the SAW filter in the first and second stages. In the finishing process of the third stage, however, CMP (Chemical Mechanical Processing) is typically executed. In that case, the average roughness Ra of the main surface of formed substrate would be about 5 nm. If the main surface of substrate formed of polycrystalline spinel is polished using CMP, considerable unevenness remains at the boundary of crystal grains on the main surface after polishing. In contrast, if finishing process is done using diamond abrasive grains, the unevenness at the grain boundary of polycrystalline structure forming the spinel substrate can also be polished and made flat. From the foregoing, it can be understood that the average roughness Ra of main surface 1a comes to have very good value because of the finishing process using diamond abrasive grains.

### EXAMPLE 1

The values PV and Ra of substrate 1 having main surface 1a polished in accordance with the manufacturing method of the embodiment and a substrate formed of spinel not subjected to such polishing were compared, and state of bonding to piezoelectric substrate was inspected. First, in accordance with manufacturing steps (S10) to (S30) shown in FIG. 6, twenty sintered bodies as the original form of spinel substrates were formed. Thereafter, at the processing step of step (S40), main surfaces of the sintered bodies were polished. Specifically, among the twenty sintered bodies, some were subjected only to the steps (S41) to (S43) of FIG. 7, and remaining sintered bodies were subjected to all of the steps (S41) to (S44) of FIG. 7.

Specifically, at the slicing step performed at the start of step (S40), the sintered body was cut such that the main surface 1a come to have a substantially circular shape of 100 mm in diameter. Thereafter, at step (S41), main surface 1a was polished for 20 minutes using GC abrasive grinder with abrasive grains of count #800. Thereafter, at step (S42), main surface 1a was polished for 20 minutes using a single-side polisher with diamond grinder of which abrasive grains had counts of 3 to 5 μm.

Thereafter, at step (S43), main surface 1a was polished for 30 minutes using a single-side polisher with diamond grinder of which abrasive grains had grain diameter of 0.5 to 1.0 μm. Finally, at step (S44), CMP process was done for 30 to 60 minutes using a single-side polisher.

For substrate 1 formed through the above-described steps, the values PV and Ra of main surface 1a after the step (S43) and before the step (S44) of CMP and main surface 1a after the step (S44) were measured, respectively. Here, the values PV and Ra were measured using an AFM (Atomic Force Microscope). The scope of measurement was an area of 0.176 mm×0.132 mm on main surface 1a.

Further, to main surface 1a after the step (S43) and before the step (S44) of CMP (in Table 1 below, “before CMP”) and to main surface 1a after the step (S44) (in Table 1 below, “after CMP”), a 4-inch LT wafer as a piezoelectric wafer was bonded, utilizing van der Waals interaction. After bonding, ratio of voids generated between the boding surfaces of the two was measured. Results of measurements are as shown in Table 1 below.

TABLE 1

| | Before CMP | After CMP |
|---|---|---|
| PV | 9.364 nm | 4.190 nm |
| Ra | 0.775 nm | 0.326 nm |
| Ratio of voids | 100% | 10% |

From Table 1, it can be seen that by performing CMP after polishing main surface 1a with diamond abrasive grains, the values PV and Ra of main surface 1a can be made smaller. Further, by such a process, the state of bonding between main surface 1a and the piezoelectric substrate can be improved, and generation of voids that degrades the state of bonding between the two bonding surfaces can be reduced.

### EXAMPLE 2

Substrate 1 having the main surface 1a polished in accordance with the manufacturing method of the present invention, a substrate formed of spinel not subjected to such polishing, and a substrate formed of sapphire single crystal were compared to inspect difference in level at grain boundary, flatness, TTV (Total Thickness Variation) and warpage.

Here, the difference in level at grain boundary means the difference in level particularly at the grain boundary of spinel crystals. The flatness particularly represents unevenness of main surface 1a and, more specifically, it represents the largest level difference on main surface 1a. TTV represents difference between the maximum and minimum values of height of main surface 1a measured in the thickness direction of substrate 1, with the main surface (back surface) opposite to the main surface 1a as the object of measurement of substrate 1 being used as a reference surface. Further, warpage represents the degree of curving of the main surface of substrate 1 as a whole.

Here, four substrates formed of spinel having the diameter of 4 inches, and two substrates formed of sapphire having the diameter of 4 inches were prepared, and each of the substrates were subjected to polishing of steps (S41) to (S44) as in Example 1.

For the main surface of substrates formed of sapphire (in Table 2 below, “sapphire”), various parameters as mentioned above of the main surface after the step (S44) of CMP were measured. For the substrates formed of spinel, various parameters as mentioned above of main surface 1a after the step (S43) and before the step (S44) of CMP (in Table 2, “spinel before CMP”) and of main surface 1a after the step S44 (in Table 2 below, “spinel after CMP”) were measured.

Here, the difference in level at grain boundary was measured by using AFM: VN-8000 manufactured by KEYENCE. The scope of measurement of level difference was 200 μm×200 μm.

The flatness, TTV and warpage were measured using FM200XRA-Wafer (Corning Tropel). Results of measurements are as shown in Table 2 below.

TABLE 2

| | | |
|---|---|---|
| | Spinel | Spinel |
| Sapphire | before CMP | after CMP |

| | | |
|---|---|---|
| Level difference | Average | Average |
| at grain boundary | about 6 nm, | about 3 nm, |
| | max 18 nm | max 18 nm |

| | | | | | | |
|---|---|---|---|---|---|---|
| Flatness | 300 | nm | 450 | nm | 330 | nm |
| TTV | 1.0 | μm | 1.2 | μm | 1.2 | μm |
| Warpage | 13 | μm | 101 | μm | 99 | μm |

It can be seen from Table 2 that the spinel substrate not subjected to CMP and the spinel substrate subjected to CMP have comparable values of level difference at grain boundary, flatness, TTV and warpage. Therefore, it can be understood that comparable quality can be ensured if the main surface of spinel substrate is subjected to CMP or not subjected to CMP. Further, from the comparison between sapphire substrates and spinel substrates, it can be seen that the substrates have comparable values, particularly of flatness and TTV, except for the warpage.

The embodiments as have been described here are mere examples and should not be interpreted as restrictive. The scope of the present invention is determined by each of the claims with appropriate consideration of the written description of the embodiments and embraces modifications within the meaning of, and equivalent to, the languages in the claims.

### INDUSTRIAL APPLICABILITY

The present invention is particularly superior as a technique for providing a substrate having an appropriate strength and allowing firm bonding to a piezoelectric substrate and the like at a low cost.

### REFERENCE SIGNS LIST

1 substrate, 1a main surface, 2 SAW filter, 3, 4 electrode, 3a, 4a first electrode, 3b, 4b second electrode, 3c, 3d comb component, 5 BAW filter, 6 lower electrode, 7 upper electrode, 8 piezoelectric film, 9 hollow cavity, 10 piezoelectric substrate, 11 low impedance film, 12 high impedance film, 20 resonator.

1. A substrate formed of spinel for an SAW device.

2. The substrate according to claim 1, wherein one main surface of said substrate has a value Ra of average roughness of at least 0.01 nm and at most 3.0 nm.

3. An SAW device using the substrate according to claim 1.

4. The substrate according to claim 1, having Young's modulus of at least 150 GPa and at most 350 GPa.

5. A substrate formed of spinel for a device.

6. The substrate according to claim 5, having Young's modulus of at least 150 GPa and at most 350 GPa.

7. A device using the substrate according to claim 5.

8. A substrate formed of spinel for an SAW device, wherein one main surface of said substrate has a value PV of level difference of at least 2 nm and at most 8 nm.

9. The substrate according to claim 8, wherein one main surface of said substrate has a value Ra of average roughness of at least 0.01 nm and at most 0.5 nm.

10. A method of forming a substrate of spinel for an SAW device, comprising the steps of:
preparing said substrate; and
conducting chemical mechanical polishing on one main surface of said substrate.

11. The method of manufacturing a substrate according to claim 10, wherein
one main surface of said substrate after said step of conducting chemical mechanical polishing has PV value of at least 2 nm and at most 8 nm.

12. The method of manufacturing a substrate according to claim 11, wherein
one main surface of said substrate after said step of conducting chemical mechanical polishing has Ra value of at least 0.01 nm and at most 0.5 nm.
